(19) United States
(12) Patent Application Publication
(10) Pub. No.: US 2014/0056082 A1
(43) Pub. Date: Feb. 27, 2014

(54) SEMICONDUCTOR DEVICES INCLUDING REDUNDANCY CELLS

(71) Applicant: SK HYNIX INC., Icheon-si (KR)

(72) Inventor: Yeon Hee PARK, Gwangju (KR)

(73) Assignee: SK hynix Inc., Icheon-si (KR)

(21) Appl. No.: 13/718,996

(22) Filed: Dec. 18, 2012

(30) Foreign Application Priority Data
Aug. 23, 2012 (KR) 10-2012-0092523

(51) Int. Cl. G11C 29/04

(52) U.S. Cl. CPC G11C 29/04
USPC 365/189.07

(57) ABSTRACT

Semiconductor devices including redundancy cells are provided. The semiconductor device includes a control signal generator and a comparator. The control signal generator generates a first control signal including a pulse generated in synchronization with a point of time that a row address enable signal is disabled, a second control signal including a pulse generated in synchronization with a point of time that the row address enable signal is enabled, and a fuse control signal which is enabled during a predetermined period from a point of time that the pulse of the first control signal or the pulse of the second control signal occurs. The comparator generates a comparison signal in response to the pulse of the first control signal or in response to the pulse of the second control signal.

### CROSS-REFERENCE TO RELATED APPLICATION

The present application claims priority under 35 U.S.C 119(a) to Korean Application No. 10-2012-0092523, filed on Aug. 23, 2012, in the Korean Intellectual Property Office, which is incorporated herein by reference in its entirety as set forth in full.

### BACKGROUND

1. Technical Field

Embodiments of the present disclosure generally relate to semiconductor devices and, more particularly, to semiconductor devices including redundancy cells.

2. Related Art

In general, semiconductor devices, for example, semiconductor memory devices include a plurality memory cells. As the semiconductor devices become more highly integrated with development of process technologies, the number of the memory cells included in the semiconductor devices has been more increased. However, if even one of the memory cells in the semiconductor device does not normally operate, the semiconductor device may malfunction. The semiconductor device including at least one failed memory cell may be categorized as a bad chip, and the bad chip cannot be employed and used in an electronic system. However, recently, the number of the failed memory cells in the semiconductor device has been reduced with the development of process technologies. Thus, most the semiconductor devices are fabricated to include redundancy memory cells, and the failed memory cells of the semiconductor devices may be replaced with the redundancy memory cells using various repair techniques to increase the yield of the semiconductor devices.

Further, the semiconductor devices may include fuse circuits which are capable of programming the addresses of the failed memory cells. Here, the term “programming” means a series of operations for storing the addresses of the failed memory cells in the fuse circuits.

As described above, the fuse circuits may store the addresses of the failed memory cells (e.g., cells to be repaired). That is, the addresses of the failed memory cells may be programmed in the fuse circuits, and repair operations may be executed using the addresses of the failed memory cells which are programmed in the fuse circuits. In more detail, if a failed memory cell of a semiconductor device is selected by a certain address, the semiconductor device may compare the certain address with the addresses of the failed memory cells stored in the fuse circuit and may replace the failed memory cell with a redundancy memory cell corresponding to the failed memory cell according to the comparison results.

### SUMMARY

Various embodiments are directed to semiconductor devices including redundancy cells.

According to various embodiments, a semiconductor device includes a control signal generator and a comparator. The control signal generator generates a first control signal including a first pulse generated in synchronization with a reset signal and a second pulse generated in synchronization with a point of time that a row address enable signal is disabled, a second control signal including a pulse generated in synchronization with a point of time that the row address enable signal is enabled, and a fuse control signal which is enabled during a predetermined period whenever the first and second pulses of the first control signal and the pulse of the second control signal occur. The comparator generates a comparison signal in response to the first and second pulses of the first control signal or in response to the pulse of the second control signal. The comparison signal is generated by comparing a fuse signal generated according to an address of a failed memory cell in a first cell block in response to the first and second pulses of the first control signal with an address signal or by comparing another fuse signal generated according to an address of a failed memory cells in a second cell block in response to the pulse of the second control signal with the address signal.

According to various embodiments, a semiconductor device includes a control signal generator and a comparator. The control signal generator generates a first control signal including a pulse generated in synchronization with a point of time that a row address enable signal is disabled, a second control signal including a pulse generated in synchronization with a point of time that the row address enable signal is enabled, and a fuse control signal which is enabled during a predetermined period from a point of time that the pulse of the first control signal or the pulse of the second control signal occurs. The comparator generates a comparison signal in response to the pulse of the first control signal or in response to the pulse of the second control signal. The comparison signal is generated by comparing a fuse signal generated according to an address of a failed memory cell in a first cell block in response to the pulse of the first control signal with an address signal or by comparing another fuse signal generated according to an address of a failed memory cells in a second cell block in response to the pulse of the second control signal with the address signal.

### BRIEF DESCRIPTION OF THE DRAWINGS

Embodiments of the inventive concept will become more apparent in view of the attached drawings and accompanying detailed description, in which:

FIG. 1 is a block diagram illustrating a configuration of a semiconductor device according to various embodiments;

FIG. 2 is a block diagram illustrating a configuration of a fuse circuit included in the semiconductor device of FIG. 1;

FIG. 3 is a circuit diagram illustrating a first drive control signal generator of a drive control signal generator shown in FIG. 2;

FIG. 4 is a circuit diagram illustrating a second drive control signal generator of a drive control signal generator shown in FIG. 2;

FIG. 5 is a circuit diagram illustrating a comparator included in the fuse circuit of FIG. 2;

FIG. 6 is a circuit diagram illustrating a first repair signal generator of a repair signal generator shown in FIG. 2;

FIG. 7 is a circuit diagram illustrating a second repair signal generator of a repair signal generator shown in FIG. 2; and

FIG. 8 is a timing diagram illustrating a repair operation of a first cell block and a second cell block of a semiconductor device according to various embodiments.

### DETAILED DESCRIPTION

Various embodiments will be described hereinafter with reference to the accompanying drawings. However, the embodiments described herein are for illustrative purposes only and are not intended to limit the scope of the inventive concept.

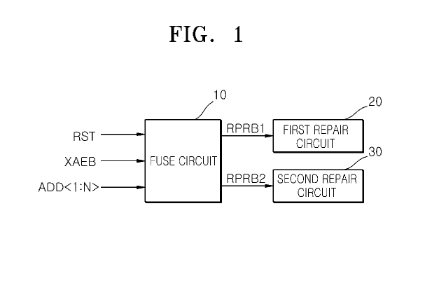

FIG. 1 is a block diagram illustrating a configuration of a semiconductor device according to various embodiments.

As illustrated in FIG. 1, the semiconductor device according to various embodiments may be configured to include a fuse circuit 10, a first repair circuit 20 and a second repair circuit 30.

The fuse circuit 10 may receive a reset signal RST, a row address enable signal XAEB and an address signal ADD<1:N> to generate a first repair signal RPRB1 and a second repair signal RPRB2 which are enabled when the address signal ADD<1:N> corresponds to an address of a failed cell. The first repair circuit 20 may execute a repair operation of a first cell block in the semiconductor device when the first repair signal RPRB1 is enabled. The second repair circuit 30 may execute a repair operation of a second cell block in the semiconductor device when the second repair signal RPRB2 is enabled. If the repair operations of the first and second cell blocks are executed, addresses of failed memory cells in the first and second cell blocks may be replaced with addresses of redundancy memory cells.

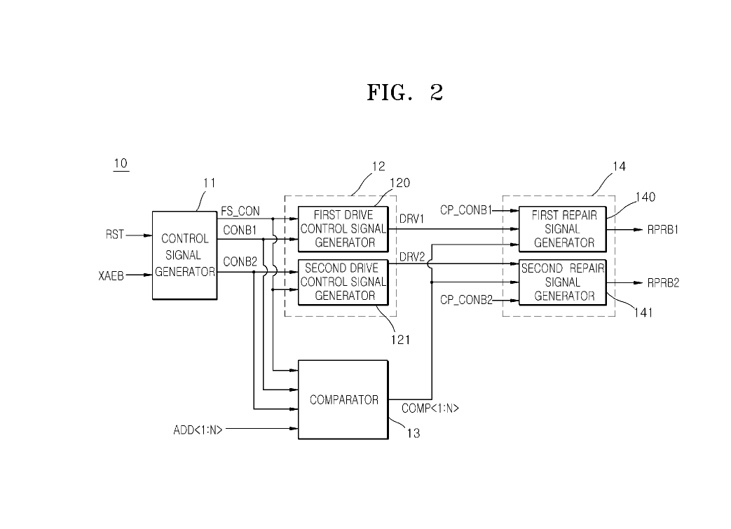

The configuration of the fuse circuit 10 will be described more fully hereinafter with reference to FIG. 2.

Referring to FIG. 2, the fuse circuit 10 may be configured to include a control signal generator 11, a drive control signal generator 12, a comparator 13 and a repair signal generator 14.

The control signal generator 11 may generate a first control signal CONB1 including a first pulse generated while a pulse of the reset signal RST is inputted and a second pulse generated in synchronization with a point of time that the row address enable signal XAEB is disabled. Further, the control signal generator 11 may generate a second control signal CONB2 including a pulse generated in synchronization with a point of time that the row address enable signal XAEB is enabled. Moreover, the control signal generator 11 may generate a fuse control signal FS_CON which is enabled during a predetermined period whenever the first and second pulses of the first control signal CONB1 and the pulse of the second control signal CONB2 occur. The reset signal RST may be a signal including a pulse generated after a power-up period that an internal voltage of the semiconductor device rises according to a power voltage. In addition, when the row address enable signal XAEB is enabled, the semiconductor device receives address signals.

The drive control signal generator 12 may be configured to include a first drive control signal generator 120 and a second drive control signal generator 121.

The first drive control signal generator 120 may receive the fuse control signal FS_CON and the first control signal CONB1 to generate a first drive control signal DRV1 when at least one failed memory cell exists in the first cell block. Similarly, the second drive control signal generator 121 may receive the fuse control signal FS_CON and the second control signal CONB2 to generate a second drive control signal DRV2 when at least one failed memory cell exists in the second cell block. The comparator 13 may receive the fuse control signal FS_CON to generate a comparison signal COMP<1:N> which is enabled when the address signal ADD<1:N> indicates the address of the failed memory cell in the first cell block while the first and second pulses of the first control signal CONB1 are inputted. Furthermore, the comparison signal COMP<1:N> may also be generated and enabled in response to the fuse control signal FS_CON when the address signal ADD<1:N> indicates the address of the failed memory cell in the second cell block while the pulse of the second control signal CONB2 are inputted.

The repair signal generator 14 may be configured to include a first repair signal generator 140 and a second repair signal generator 141.

The first repair signal generator 140 may receive a first comparison control signal CP_CONB1 to generate the first repair signal RPRB1 in response to the first drive control signal DRV1 and the comparison signal COMP<1:N>. The second repair signal generator 141 may receive a second comparison control signal CP_CONB2 to generate the second repair signal RPRB2 in response to the second drive control signal DRV2 and the comparison signal COMP<1:N>. The first comparison control signal CP_CONB1 may include a pulse which is generated after a first delay time from a point of time that the row address enable signal XAEB is enabled. Further, the second comparison control signal CP_CONB2 may include a pulse which is generated after a second delay time from a point of time that the pulse of the first comparison control signal CP_CONB1 occurs.

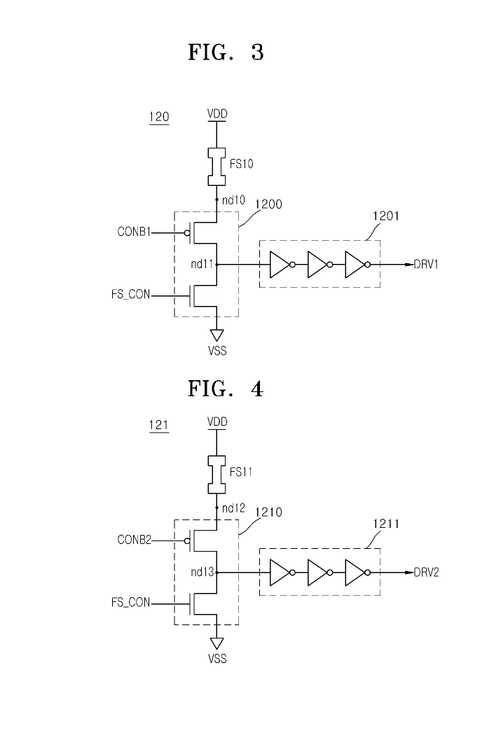

The configuration of the first drive control signal generator 120 will be described more fully hereinafter with reference to FIG. 3.

Referring to FIG. 3, the first drive control signal generator 120 may include a first fuse FS10 having a first end electrically connected to a power voltage terminal VDD and a second end electrically connected to a first node ND10, a first driver 1200 having a first end electrically connected to the first node ND10 and a second end electrically connected to a ground terminal VSS, and a first buffer 1201 connected to an output terminal (e.g., a second node ND11) of the first driver 1200. The first fuse FS10 may be cut when the first cell block has at least one failed memory cell. The first driver 1200 may pull down a voltage level of the second node ND11 while the fuse control signal FS_CON is enabled and may pull up the voltage level of the second node ND11 according to whether the first fuse FS10 is cut or not while the first and second pulses of the first control signal CONB1 are inputted. Further, the first buffer 1201 may buffer a signal outputted from the second node ND11 to generate the first drive control signal DRV1. In various embodiments, the first fuse FS10 may be configured to include an antifuse.

The configuration of the second drive control signal generator 121 will be described more fully hereinafter with reference to FIG. 4.

Referring to FIG. 3, the second drive control signal generator 121 may include a second fuse FS11 having a first end electrically connected to the power voltage terminal VDD and a second end electrically connected to a third node ND12, a second driver 1210 having a first end electrically connected to the third node ND12 and a second end electrically connected to the ground terminal VSS, and a second buffer 1211 connected to an output terminal (e.g., a fourth node ND13) of the second driver 1210. The second fuse FS11 may be cut when the second cell block has at least one failed memory cell. The second driver 1210 may pull down a voltage level of the fourth node ND13 while the fuse control signal FS_CON is enabled and may pull up the voltage level of the fourth node ND13 according to whether the second fuse FS11 is cut or not while the pulse of the second control signal CONB2 is inputted. Further, the second buffer 1211 may buffer a signal outputted from the fourth node ND13 to generate the second drive control signal DRV2. In various embodiments, the second fuse FS11 may be configured to include an anti-fuse.

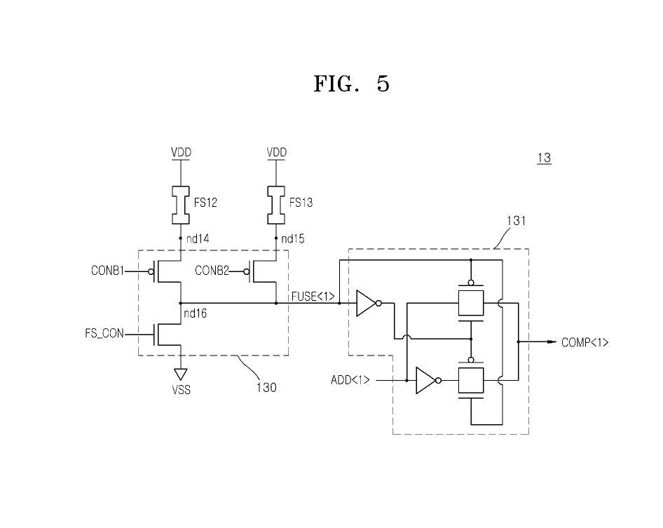

The configuration of the comparator 13 will be described more fully hereinafter with reference to FIG. 5.

Referring to FIG. 5, the comparator 13 (see FIG. 2) may be configured to include a third fuse FS12 having a first end electrically connected to the power voltage terminal VDD and a second end electrically connected to a fifth node ND14, a fourth fuse FS13 having a first end electrically connected to the power voltage terminal VDD and a second end electrically connected to a sixth node ND15, a fuse signal generator 130 that is electrically connected to the fifth and sixth nodes ND14 and ND15 and the ground terminal VSS to have a seventh node ND16 acting as an output terminal, and a transmitter 131 electrically connected to the seventh node ND16.

The third fuse FS12 may be selectively cut according to the addresses of the failed memory cells in the first cell block and the fourth fuse FS13 may be selectively cut according to the addresses of the failed memory cells in the second cell block. The fuse signal generator 130 may pull down a voltage level of the seventh node ND16 while the fuse control signal FS_CON is enabled, thereby generating a fuse signal FUSE<1> having a logic level “0”. Further, the fuse signal generator 130 may pull up a voltage level of the seventh node ND16 according to whether the third fuse FS12 is cut or not while the first and second pulses of the first control signal CONB1 are inputted or according to whether the fourth fuse FS13 is cut or not while the pulse of the second control signal CONB2 is inputted, thereby generating a fuse signal FUSE<1> having a logic level “1”.

The transmitter 131 may buffer or inversely buffer the address signal ADD<1> according to the logic level of the fuse signal FUSE<1> and may output the buffered address signal ADD<1> or the inversely buffered address signal ADD<1> as the comparison signal COMP<1>. That is, the comparator 13 may compare the fuse signal FUSE<1:N> (i.e., FUSE<1>), which is generated according to the addresses of the failed memory cells in the first cell block in response to the first and second pulses of the first control signal CONB1, with the address signal ADD<1:N> (i.e., ADD<1>) to generate the comparison signal COMP<1:N> (i.e., COMP<1>). In addition, the comparator 13 may also compare the fuse signal FUSE<1:N>, which is generated according to the addresses of the failed memory cells in the second cell block in response to the pulse of the second control signal CONB2, with the address signal ADD<1:N> to generate the comparison signal COMP<1:N>. If the logic level of the fuse signal FUSE<1:N> generated according to the address of the failed memory cell is different from the logic level of the address signal ADD<1:N>, the address defined by the address signal ADD<1:N> may be consistent with the address of the failed memory cell. In various embodiments, each of the third and fourth fuses FS12 and FS13 may be configured to include an anti-fuse.

The semiconductor device according to the embodiments may be configured to include a plurality of comparators 13 (see also FIG. 2) having the same number as the bits of the address signal ADD<1:N>. In such a case, the plurality of comparators 13 may compare the fuse signal FUSE<1:N> with the address signal ADD<1:N> to generate the comparison signal COMP<1:N>. [to stay consistent with the other figures FIG. 5 was labeled with 13 to indicate that the comparator is being shown from FIG. 2.]

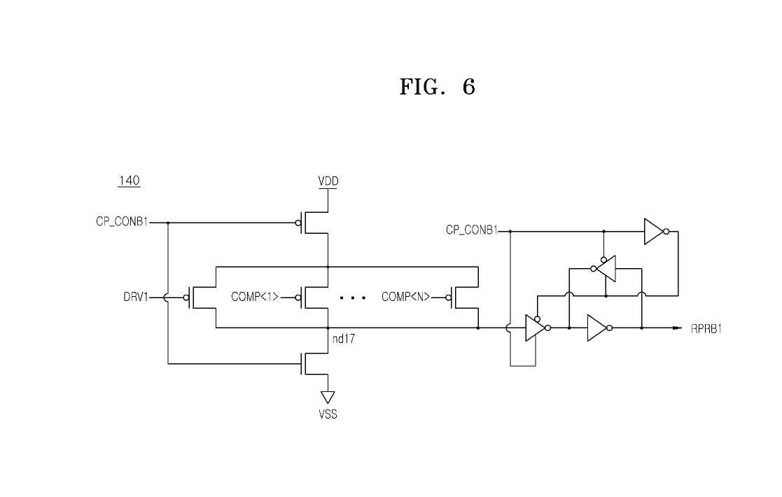

The configuration of the first repair signal generator 140 will be described more fully hereinafter with reference to FIG. 6.

Referring to FIG. 6, the first repair signal generator 140 may pull down a voltage level of an eighth node ND17 while the pulse of the first comparison control signal CP_CONB1 does not occur and may pull up a voltage level of the eighth node ND17 according to the first drive control signal DRV1 and the comparison signal COMP<1:N> while the pulse of the first comparison control signal CP_CONB1 occurs, there by generating the first repair signal RPRB1. As illustrated in FIG. 6, there exists a power voltage terminal VDD and a ground terminal VSS.

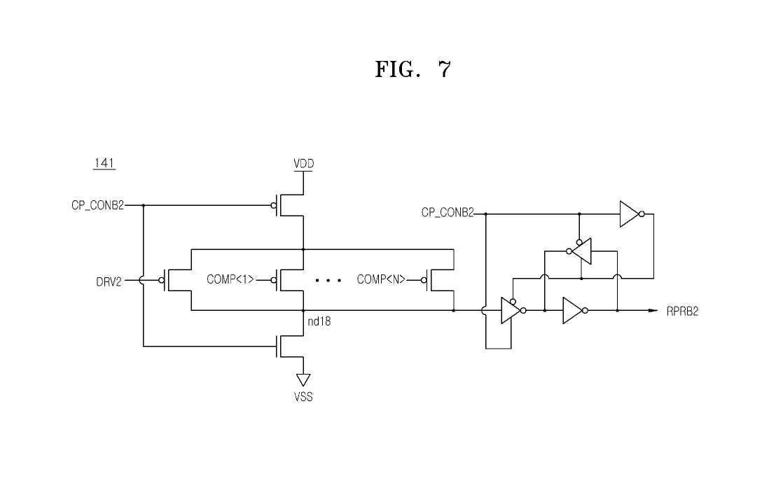

The configuration of the second repair signal generator 141 will be described more fully hereinafter with reference to FIG. 7.

Referring to FIG. 7, the second repair signal generator 141 may pull down a voltage level of a ninth node ND18 while the pulse of the second comparison control signal CP_CONB2 does not occur and may pull up a voltage level of the ninth node ND18 according to the second drive control signal DRV2 and the comparison signal COMP<1:N> while the pulse of the second comparison control signal CP_CONB2 occurs, there by generating the second repair signal RPRB2. As illustrated in FIG. 7, there exists a power voltage terminal VDD and a ground terminal VSS.

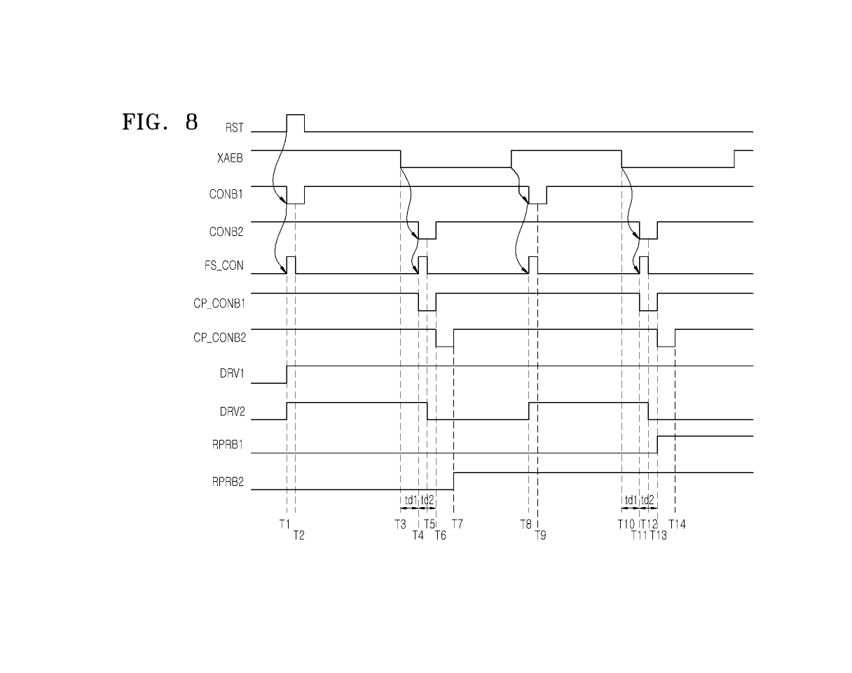

The operations of the semiconductor device according to the embodiments will be described hereinafter with reference to FIGS. 1 to 8. The following descriptions will be developed based on an example that the first cell block includes failed memory cells and the second cell block does not include any failed memory cells. In such a case, there may be two repair operations. That is, a first repair operation may be executed when the address indicated by the address signal ADD<1:N> is consistent with the address of the failed memory cell, and a second repair operation may be executed when the address indicated by the address signal ADD<1:N> is inconsistent with the address of the failed memory cell.

The first repair operation will now be described below.

First, at a point of time “T1” after, for example, a power-up period ends, the control signal generator 11 of the fuse circuit 10 may receive the reset signal RST including a pulse that rises up to a logic “high” level, thereby pulling down the first control signal CONB1 to a logic “low” level and pulling up the second control signal CONB2 and the fuse control signal FS_CON to a logic “high” level.

The first driver 1200 of the first drive control signal generator 120 may receive the fuse control signal FS_CON having a logic “high” level to pull down a voltage level of the second node ND11. The first buffer 1201 may inversely buffer the pulled-down signal of the second node ND11 to generate the first drive control signal DRV1 having a logic “high” level. In such a case, since the first control signal CONB1 has a logic “low” level, the first node ND10 may also be pulled down to cause an excessive current flowing through the first fuse FS10. As a result, the first fuse FS10 may be cut. That is, in the event that the first cell block includes failed memory cells, the first fuse FS10 may be cut.

The second driver 1210 of the second drive control signal generator 121 may receive the fuse control signal FS_CON having a logic “high” level to pull down a voltage level of the fourth node ND13. The second buffer 1211 may inversely buffer the pulled-down signal of the fourth node ND13 to generate the second drive control signal DRV2 having a logic “high” level. In such a case, since the second control signal CONB2 has a logic “high” level, the third node ND12 may be floated and no excessive current may flow through the second fuse FS11. As a result, the second fuse FS11 may not be cut. That is, in the event that the second cell block does not include any failed memory cells, the second fuse FS11 may not be cut.

The fuse signal generator 130 of the comparator 13 may receive the fuse control signal FS_CON having a logic “high” level to pull down a voltage level of the seventh node ND16. Accordingly, the transmitter 131 may not generate the comparison signal COMP<1:N>.

The first repair signal generator 140 may receive the first comparison control signal CP_CONB1 having a logic “high” level to pull down a voltage level of the eighth node ND17. Thus, the first repair signal generator 140 may not generate the first repair signal RPRB1.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T2”, the control signal generator 11 of the fuse circuit 10 may generate the first control signal CONB1 having a logic “low” level, the second control signal CONB2 having a logic “high” level, and the fuse control signal FS_CON having a logic “low” level.

The first driver 1200 of the first drive control signal generator 120 may receive the first control signal CONB1 having a logic “low” level and may not pull up a voltage level of the second node ND11 because the first drive control signal generator 120 has the first fuse FS10 which is cut. Thus, the first buffer 1201 may inversely buffer the signal of the second node ND11 to generate the first drive control signal DRV1 having a logic “high” level.

The second driver 1210 of the second drive control signal generator 121 may receive the second control signal CONB2 having a logic “high” level and may not pull up a voltage level of the fourth node ND13. Thus, the second buffer 1211 may inversely buffer the signal of the fourth node ND13 to generate the second drive control signal DRV2 having a logic “high” level.

The fuse signal generator 130 of the comparator 13 may receive the first control signal CONB1 having a logic “low” level and may drive the seventh node ND16 according to an on/off state of the third fuse FS12, which is cut by the address of the failed memory cell in the first block, to generate the fuse signal FUSE<1>. The transmitter 131 may buffer the address signal ADD<1> according to a logic level of the fuse signal FUSE<1> to generate the comparison signal COMP<1>. The semiconductor device may include a plurality of comparators 13 having the same number as the bits of the address signal ADD<1:N> to generate the fuse signal FUSE<1:N>, and the plurality of comparators 13 may compare the fuse signal FUSE<1:N> with the address signal ADD<1:N> to generate the comparison signal COMP<1:N>. That is, the plurality of comparators 13 may generate the comparison signal COMP<1:N> whose all bits have a logic “high” level because the address indicated by the address signal ADD<1:N> is consistent with the address of the failed memory cell in the first cell block.

The first repair signal generator 140 may receive the first comparison control signal CP_CONB1 having a logic “high” level to pull down a voltage level of the eighth node ND17. Thus, the first repair signal generator 140 may not generate the first repair signal RPRB1.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, the control signal generator 11 may be synchronized with the row address enable signal XAEB enabled to have a logic “low” level at a point of time “T3”, thereby generating the first control signal CONB1 having a logic “high” level, the second control signal CONB2 having a logic “low” level and the fuse control signal FS_CON having a logic “high” level at a point of time “T4”.

At the point of time “T4”, the first driver 1200 of the first drive control signal generator 120 may receive the fuse control signal FS_CON having a logic “high” level to pull down a voltage level of the second node ND11. The first buffer 1201 may buffer the pulled-down signal of the second node ND11 to generate the first drive control signal DRV1 having a logic “high” level.

The second driver 1210 of the second drive control signal generator 121 may receive the fuse control signal FS_CON having a logic “high” level to pull down a voltage level of the fourth node ND13. The second buffer 1211 may buffer the pulled-down signal of the fourth node ND13 to generate the second drive control signal DRV2 having a logic “high” level.

The fuse signal generator 130 of the comparator 13 may receive the fuse control signal FS_CON having a logic “high” level to pull down a voltage level of the seventh node ND16. As a result, the fuse signal generator 130 may generate the fuse signal FUSE<1:N> having a logic “low” level.

The first repair signal generator 140 may not pull up a voltage level of the eighth node ND17 in response to the first comparison control signal CP_CONB1 including a low level pulse which is generated after a first delay time TD1 from the point of time “T3” that the row address enable signal XAEB is enabled. This is because the first drive control signal DRV1 has a logic “high” level and all bits of the comparison signal COMP<1:N> generated at the point of time “T2” also have a logic “high” level.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T5”, the control signal generator 11 of the fuse circuit 10 may generate the first control signal CONB1 having a logic “high” level, the second control signal CONB2 having a logic “low” level and the fuse control signal FS_CON having a logic “low” level.

The first driver 1200 of the first drive control signal generator 120 may receive the first control signal CONB1 having a logic “high” level. Thus, the first driver 1200 may not pull up a voltage level of the second node ND11, and the first buffer 1201 may inversely buffer a signal of the second node ND11 to generate the first drive control signal DRV1 having a logic “high” level.

The second driver 1210 of the second drive control signal generator 121 may receive the second control signal CONB2 having a logic “low” level to pull up a voltage level of the fourth node ND13 because the third node ND12 is still electrically connected to the power voltage terminal VDD through the second fuse FS11. The second buffer 1211 may inversely buffer a signal of the fourth node ND13 to generate the second drive control signal DRV2 having a logic “low” level.

The fuse signal generator 130 of the comparator 13 may receive the second control signal CONB2 having a logic “low” level and may pull up a voltage level of the seventh node ND16, thereby generating the fuse signal FUSE<1>. This is because no failed memory cells exist in the second cell block and the fourth fuse FS13 still electrically connects the sixth node ND15 to the power voltage terminal VDD. The transmitter 131 may inversely buffer the address signal ADD<1> in response to the fuse signal FUSE<1> having a logic “high” level to generate the comparison signal COMP<1>. The semiconductor device may include a plurality of comparators 13 having the same number as the bits of the address signal ADD<1:N> to generate the fuse signal FUSE<1:N>, and the plurality of comparators 13 may compare the fuse signal FUSE<1:N> with the address signal ADD<1:N> to generate the comparison signal COMP<1:N>. That is, the comparators 13 may inversely buffer the address signal ADD<1:N> to generate the comparison signal COMP<1:N> because no failed memory cells exist in the second cell block.

The first repair signal generator 140 may not pull up a voltage level of the eighth node ND17 in response to the first comparison control signal CP_CONB1 having a logic “low’ level. This is because the first drive control signal DRV1 has a logic “high” level and all bits of the comparison signal COMP<1:N> also have a logic “high” level.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T6”, the control signal generator 11 of the fuse circuit 10 may generate the first control signal CONB1 having a logic “high” level, the second control signal CONB2 having a logic “high” level and the fuse control signal FS_CON having a logic “low” level.

The first repair signal generator 140 may receive the first comparison control signal CP_CONB1 having a logic “high’ level to generate the first repair signal RPRB1 having a logic “low” level because a voltage level of the eighth node ND17 is pulled down at the point of time “T5”. At this time, the first repair circuit 20 may execute a repair operation for replacing the address indicated by the address signal ADD<1:N> with the address of the redundancy memory cell corresponding to the failed memory cell in response to the first repair signal RPRB1 having a logic “low” level.

The second repair signal generator 141 may pull up a voltage level of the ninth node ND18 in response to the second comparison control signal CP_CONB2 including a low level pulse which is generated after a second delay time TD2 from a point of time that the low level pulse of first comparison control signal CP_CONB1 is generated and in response to the second drive control signal DRV2 which is generated to have a logic “low” level at the point of time “T5”.

Next, at a point of time “T7”, the second repair signal generator 141 may receive the second comparison control signal CP_CONB2 having a logic “high’ level to generate the second repair signal RPRB2 having a logic “high” level because a voltage level of the ninth node ND18 is pulled up at the point of time “T6”. At this time, the second repair circuit 30 may not execute any repair operations in response to the second repair signal RPRB2 having a logic “high” level.

Hereinafter, the second repair operation, which is executed when the address indicated by the address signal ADD<1:N> is inconsistent with the address of the failed memory cell, will be described.

First, at a point of time “T8”, the control signal generator 11 of the fuse circuit 10 may be synchronized with a point of time that the row address enable signal XAEB is disabled, thereby generating the first control signal CONB1 having a logic “low” level, the second control signal CONB2 having a logic “high” level and the fuse control signal FS_CON having a logic “high” level.

The first driver 1200 of the first drive control signal generator 120 may receive the fuse control signal FS_CON having a logic “high” level to pull down a voltage level of the second node ND11. The first buffer 1201 may inversely buffer the pulled-down signal of the second node ND11 to generate the first drive control signal DRV1 having a logic “high” level. In such a case, since the first control signal CONB1 has a logic “low” level, the first node ND10 may also be pulled down to cause an excessive current flowing through the first fuse FS10. As a result, the first fuse FS10 may be cut. That is, in the event that the first cell block includes failed memory cells, the first fuse FS10 may be cut.

The second driver 1210 of the second drive control signal generator 121 may receive the fuse control signal FS_CON having a logic “high” level to pull down a voltage level of the fourth node ND13. The second buffer 1211 may inversely buffer the pulled-down signal of the fourth node ND13 to generate the second drive control signal DRV2 having a logic “high” level. In such a case, since the second control signal CONB2 has a logic “high” level, the third node ND12 may be floated and no excessive current may flow through the second fuse FS11. As a result, the second fuse FS11 may not be cut. That is, in the event that the second cell block does not include any failed memory cells, the second fuse FS11 may not be cut.

The fuse signal generator 130 of the comparator 13 may receive the fuse control signal FS_CON having a logic “high” level to pull down a voltage level of the seventh node ND16. Accordingly, the transmitter 131 may not generate the comparison signal COMP<1:N>.

The first repair signal generator 140 may receive the first comparison control signal CP_CONB1 having a logic “high” level to pull down a voltage level of the eighth node ND17. Thus, the first repair signal generator 140 may not generate the first repair signal RPRB1.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T9”, the control signal generator 11 of the fuse circuit 10 may generate the first control signal CONB1 having a logic “low” level, the second control signal CONB2 having a logic “high” level, and the fuse control signal FS_CON having a logic “low” level.

The first driver 1200 of the first drive control signal generator 120 may receive the first control signal CONB1 having a logic “low” level and may not pull up a voltage level of the second node ND11 because the first drive control signal generator 120 has the first fuse FS10 which is cut. Thus, the first buffer 1201 may inversely buffer the signal of the second node ND11 to generate the first drive control signal DRV1 having a logic “high” level.

The second driver 1210 of the second drive control signal generator 121 may receive the second control signal CONB2 having a logic “high” level and may not pull up a voltage level of the fourth node ND13. Thus, the second buffer 1211 may inversely buffer the signal of the fourth node ND13 to generate the second drive control signal DRV2 having a logic “high” level.

The fuse signal generator 130 of the comparator 13 may receive the first control signal CONB1 having a logic “low” level and may drive the seventh node ND16 according to an on/off state of the third fuse FS12, which is cut by the address of the failed memory cell in the first block, to generate the fuse signal FUSE<1>. The transmitter 131 may buffer the address signal ADD<1> according to a logic level of the fuse signal FUSE<1> to generate the comparison signal COMP<1>. The semiconductor device may include a plurality of comparators 13 having the same number as the bits of the address signal ADD<1:N> to generate the fuse signal FUSE<1:N>, and the plurality of comparators 13 may compare the fuse signal FUSE<1:N> with the address signal ADD<1:N> to generate the comparison signal COMP<1:N>. That is, the plurality of comparators 13 may generate the comparison signal COMP<1:N> including at least one bit having a logic “low” level because the address indicated by the address signal ADD<1:N> is inconsistent with the address of the failed memory cell in the first cell block.

The first repair signal generator 140 may receive the first comparison control signal CP_CONB1 having a logic “high” level to pull down a voltage level of the eighth node ND17. Thus, the first repair signal generator 140 may not generate the first repair signal RPRB1.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, the control signal generator 11 may be synchronized with the row address enable signal XAEB enabled to have a logic “low” level at a point of time “T10”, thereby generating the first control signal CONB1 having a logic “high” level, the second control signal CONB2 having a logic “low” level and the fuse control signal FS_CON having a logic “high” level at a point of time “T11”.

At the point of time “T11”, the first driver 1200 of the first drive control signal generator 120 may receive the fuse control signal FS_CON having a logic “high” level to pull down a voltage level of the second node ND11. The first buffer 1201 may buffer the pulled-down signal of the second node ND11 to generate the first drive control signal DRV1 having a logic “high” level.

The second driver 1210 of the second drive control signal generator 121 may receive the fuse control signal FS_CON having a logic “high” level to pull down a voltage level of the fourth node ND13. The second buffer 1211 may buffer the pulled-down signal of the fourth node ND13 to generate the second drive control signal DRV2 having a logic “high” level.

The fuse signal generator 130 of the comparator 13 may receive the fuse control signal FS_CON having a logic “high” level to pull down a voltage level of the seventh node ND16. As a result, the fuse signal generator 130 may generate the fuse signal FUSE<1:N> having a logic “low” level.

The first repair signal generator 140 may pull up a voltage level of the eighth node ND17 in response to the first comparison control signal CP_CONB1 including a low level pulse which is generated after a first delay time TD1 from the point of time “T10” that the row address enable signal XAEB is enabled. This is because the first drive control signal DRV1 has a logic “high” level but at least one of all bits of the comparison signal COMP<1:N> generated at the point of time “T10” has a logic “low” level.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T12”, the control signal generator 11 of the fuse circuit 10 may generate the first control signal CONB1 having a logic “high” level, the second control signal CONB2 having a logic “low” level and the fuse control signal FS_CON having a logic “low” level.

The first driver 1200 of the first drive control signal generator 120 may receive the first control signal CONB1 having a logic “high” level. Thus, the first driver 1200 may not pull up a voltage level of the second node ND11, and the first buffer 1201 may inversely buffer a signal of the second node ND11 to generate the first drive control signal DRV1 having a logic “high” level.

The second driver 1210 of the second drive control signal generator 121 may receive the second control signal CONB2 having a logic “low” level to pull up a voltage level of the fourth node ND13 because the third node ND12 is still electrically connected to the power voltage terminal VDD through the second fuse FS11. The second buffer 1211 may inversely buffer a signal of the fourth node ND13 to generate the second drive control signal DRV2 having a logic “low” level.

The fuse signal generator 130 of the comparator 13 may receive the second control signal CONB2 having a logic “low” level and may pull up a voltage level of the seventh node ND16, thereby generating the fuse signal FUSE<1>. This is because no failed memory cells exist in the second cell block and the fourth fuse FS13 still electrically connects the sixth node ND15 to the power voltage terminal VDD. The transmitter 131 may inversely buffer the address signal ADD<1> in response to the fuse signal FUSE<1> having a logic “high” level to generate the comparison signal COMP<1>. The semiconductor device may include a plurality of comparators 13 having the same number as the bits of the address signal ADD<1:N> to generate the fuse signal FUSE<1:N>, and the plurality of comparators 13 may compare the fuse signal FUSE<1:N> with the address signal ADD<1:N> to generate the comparison signal COMP<1:N>. That is, the comparators 13 may inversely buffer the address signal ADD<1:N> to generate the comparison signal COMP<1:N> because no failed memory cells exist in the second cell block.

The first repair signal generator 140 may pull up a voltage level of the eighth node ND17 in response to the first comparison control signal CP_CONB1 having a logic “low’ level. This is because the first drive control signal DRV1 has a logic “high” level but at least one of all bits of the comparison signal COMP<1:N> has a logic “low” level.

The second repair signal generator 141 may receive the second comparison control signal CP_CONB2 having a logic “high” level to pull down a voltage level of the ninth node ND18. Thus, the second repair signal generator 141 may not generate the second repair signal RPRB2.

Next, at a point of time “T13”, the control signal generator 11 of the fuse circuit 10 may generate the first control signal CONB1 having a logic “high” level, the second control signal CONB2 having a logic “high” level and the fuse control signal FS_CON having a logic “low” level.

The first repair signal generator 140 may receive the first comparison control signal CP_CONB1 having a logic “high’ level to generate the first repair signal RPRB1 having a logic “high” level because a voltage level of the eighth node ND17 is pulled up at the point of time “T13”. At this time, the first repair circuit 20 may not execute any repair operations in response to the first repair signal RPRB1 having a logic “high” level.

The second repair signal generator 141 may pull up a voltage level of the ninth node ND18 in response to the second comparison control signal CP_CONB2 including a low level pulse which is generated after a second delay time TD2 from a point of time that the low level pulse of first comparison control signal CP_CONB1 is generated and in response to the second drive control signal DRV2 which is generated to have a logic “low” level at the point of time “T12”.

Next, at a point of time “T14”, the second repair signal generator 141 may receive the second comparison control signal CP_CONB2 having a logic “high’ level to generate the second repair signal RPRB2 having a logic “high” level because a voltage level of the ninth node ND18 is pulled up at the point of time “T13”. At this time, the second repair circuit 30 may not execute any repair operations in response to the second repair signal RPRB2 having a logic “high” level.

As described above, a semiconductor device according to the embodiments may generate repair signals for a plurality of cell blocks using a comparator of a fuse circuit, thereby reducing an area of the semiconductor device. Further, the repair signals for the plurality of cell blocks may be sequentially generated by the common comparator of the fuse circuit, thereby reducing a repair time of the plurality of cell blocks.

The various embodiments have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A semiconductor device comprising:
a control signal generator configured to generate a first control signal including a first pulse generated in synchronization with a reset signal and a second pulse generated in synchronization with a point of time that a row address enable signal is disabled, a second control signal including a pulse generated in synchronization with a point of time that the row address enable signal is enabled, and a fuse control signal which is enabled during a predetermined period whenever the first and second pulses of the first control signal and the pulse of the second control signal occur; and
a comparator configured to generate a comparison signal in response to the first and second pulses of the first control signal or in response to the pulse of the second control signal,
wherein the comparison signal is generated by comparing a fuse signal generated according to an address of a failed memory cell in a first cell block in response to the first and second pulses of the first control signal with an address signal or by comparing another fuse signal generated according to an address of a failed memory cells in a second cell block in response to the pulse of the second control signal with the address signal.

2. The semiconductor device of claim 1, wherein the comparator compares the fuse signal generated according to whether a first fuse is cut or not in response to the first and second pulses of the first control signal with the address signal to generate the comparison signal.

3. The semiconductor device of claim 2, wherein the comparator compares the fuse signal generated according to whether a second fuse is cut or not in response to the pulse of the second control signal with the address signal to generate the comparison signal.

4. The semiconductor device of claim 3, wherein the comparator includes:
the first fuse having a first end electrically connected to a power voltage terminal and a second end electrically connected to a first node;
the second fuse having a first end electrically connected to the power voltage terminal and a second end electrically connected to a second node;
a fuse signal generator electrically connected to the first and second nodes and a ground terminal; and
a transmitter electrically connected to a third node acting as an output terminal of the fuse signal generator,
wherein the fuse signal generator drives the third node according to whether the first fuse is cut or not in response to the fuse control signal and the first and second pulses of the first control signal to generate the fuse signal or drives the third node according to whether the second fuse is cut or not in response to the fuse control signal and the pulse of the second control signal to generate the fuse signal, and
wherein the transmitter buffers the address signal according to a logic level of the fuse signal to output the buffered address signal as the comparison signal.

5. The semiconductor device of claim 4, wherein the fuse signal generator pulls down a voltage level of the third node while the fuse control signal is enabled and pulls up the voltage level of the third node according to whether the first fuse is cut while the first and second pulses of the first control signal are inputted.

6. The semiconductor device of claim 4, wherein the fuse signal generator pulls down a voltage level of the third node while the fuse control signal is enabled and pulls up the voltage level of the third node according to whether the second fuse is cut while the pulse of the second control signal is inputted.

7. The semiconductor device of claim 4, wherein the transmitter outputs the address signal as the comparison signal when the fuse signal has a first logic level and outputs an inversely buffered signal of the address signal as the comparison signal when the fuse signal has a second logic level.

8. The semiconductor device of claim 1, further comprising:
a drive control signal generator configured to generate a first drive control signal according to whether a third fuse is cut or not in response to the fuse control signal and the first and second pulses of the first control signal and a second drive control signal according to whether a fourth fuse is cut or not in response to the fuse control signal and the pulse of the second control signal; and
a repair signal generator configured to generate a first repair signal according to the first drive control signal and the comparison signal in synchronization with a point of time that the row address enable signal is enabled and a second repair signal according to the second drive control signal and the comparison signal.

9. The semiconductor device of claim 8, wherein the drive control signal generator includes:
a first drive control signal generator configured to generate the first drive control signal according to whether the third fuse is cut or not in response to the fuse control signal and the first and second pulses of the first control signal; and
a second drive control signal generator configured to generate the second drive control signal according to whether the fourth fuse is cut or not in response to the fuse control signal and the pulse of the second control signal.

10. The semiconductor device of claim 9, wherein the first drive control signal generator includes:
the third fuse having a first end electrically connected to a power voltage terminal and a second end electrically connected to a fourth node;
a first driver having a first end electrically connected to the fourth node and a second end electrically connected to a ground terminal; and
a first buffer electrically connected to a fifth node acting as an output terminal of the first driver,
wherein the first driver drives the fifth node in response to the fuse control signal and the first and second pulses of the first control signal, and the first buffer buffers a signal of the fifth node to generate the first drive control signal.

11. The semiconductor device of claim 10, wherein the first driver pulls down a voltage level of the fifth node while the fuse control signal is enabled and pulls up a voltage level of the fifth node while the first and second pulses of the first control signal are inputted.

12. The semiconductor device of claim 11, wherein the third fuse comprises an anti-fuse.

13. The semiconductor device of claim 9, wherein the second drive control signal generator includes:
the fourth fuse having a first end electrically connected to a power voltage terminal and a second end electrically connected to a sixth node;
a second driver having a first end electrically connected to the sixth node and a second end electrically connected to a ground terminal; and
a second buffer electrically connected to a seventh node acting as an output terminal of the second driver,
wherein the second driver drives the seventh node in response to the fuse control signal and the pulse of the second control signal, and the second buffer buffers a signal of the seventh node to generate the second drive control signal.

14. The semiconductor device of claim 13, wherein the second driver pulls down a voltage level of the seventh node while the fuse control signal is enabled and pulls up the voltage level of the seventh node while the pulse of the second control signal is inputted.

15. The semiconductor device of claim 13, wherein the fourth fuse comprises an anti-fuse.

16. The semiconductor device of claim 8, wherein the repair signal generator includes:
a first repair signal generator configured to generate the first repair signal according to the first drive control signal and the comparison signal in response to a first comparison control signal including a pulse generated after a first delay time from a point of time that the row address enable signal is enabled; and
a second repair signal generator configured to generate the second repair signal according to the second drive control signal and the comparison signal in response to a second comparison control signal including a pulse generated after a second delay time from a point of time that the pulse of the first comparison control signal occurs.

17. The semiconductor device of claim 16, wherein the first repair signal generator pulls down a voltage level of a eighth node while the pulse of the first comparison control signal does not occur and pulls up a voltage level of the eighth node according to the first drive control signal and the comparison signal while the pulse of the first comparison control signal occurs.

18. The semiconductor device of claim 16, wherein the second repair signal generator pulls down a voltage level of a ninth node while the pulse of the second comparison control signal does not occur and pulls up a voltage level of the ninth node according to the second drive control signal and the comparison signal while the pulse of the second comparison control signal occurs.

19. A semiconductor device comprising:
a control signal generator configured to generate a first control signal including a pulse generated in synchronization with a point of time that a row address enable signal is disabled, a second control signal including a pulse generated in synchronization with a point of time that the row address enable signal is enabled, and a fuse control signal which is enabled during a predetermined period from a point of time that the pulse of the first control signal or the pulse of the second control signal occurs; and
a comparator configured to generate a comparison signal in response to the pulse of the first control signal or in response to the pulse of the second control signal,
wherein the comparison signal is generated by comparing a fuse signal generated according to an address of a failed memory cell in a first cell block in response to the pulse of the first control signal with an address signal or by comparing another fuse signal generated according to an address of a failed memory cells in a second cell block in response to the pulse of the second control signal with the address signal.

20. The semiconductor device of claim 19, wherein the comparator compares the fuse signal generated according to whether a first fuse is cut or not in response to the pulse of the first control signal with the address signal to generate the comparison signal.

21. The semiconductor device of claim 20, wherein the comparator compares the fuse signal generated according to whether a second fuse is cut or not in response to the pulse of the second control signal with the address signal to generate the comparison signal.

22. The semiconductor device of claim 21, wherein the comparator includes:
the first fuse having a first end electrically connected to a power voltage terminal and a second end electrically connected to a first node;
the second fuse having a first end electrically connected to the power voltage terminal and a second end electrically connected to a second node;
a fuse signal generator electrically connected to the first and second nodes and a ground terminal; and
a transmitter electrically connected to a third node acting as an output terminal of the fuse signal generator,
wherein the fuse signal generator drives the third node according to whether the first fuse is cut or not in response to the fuse control signal and the pulse of the first control signal to generate the fuse signal or drives the third node according to whether the second fuse is cut or not in response to the fuse control signal and the pulse of the second control signal to generate the fuse signal, and
wherein the transmitter buffers the address signal according to a logic level of the fuse signal to output the buffered address signal as the comparison signal.

23. The semiconductor device of claim 22, wherein the fuse signal generator pulls down a voltage level of the third node while the fuse control signal is enabled and pulls up the voltage level of the third node according to whether the first fuse is cut while the pulse of the first control signal are inputted.

24. The semiconductor device of claim 22, wherein the fuse signal generator pulls down a voltage level of the third node while the fuse control signal is enabled and pulls up the voltage level of the third node according to whether the second fuse is cut while the pulse of the second control signal is inputted.

25. The semiconductor device of claim 22, wherein the transmitter outputs the address signal as the comparison signal when the fuse signal has a first logic level and outputs an inversely buffered signal of the address signal as the comparison signal when the fuse signal has a second logic level.

26. The semiconductor device of claim 19, further comprising:
a drive control signal generator configured to generate a first drive control signal according to whether a third fuse is cut or not in response to the fuse control signal and the pulse of the first control signal and a second drive control signal according to whether a fourth fuse is cut or not in response to the fuse control signal and the pulse of the second control signal; and
a repair signal generator configured to generate a first repair signal according to the first drive control signal and the comparison signal in synchronization with a point of time that the row address enable signal is enabled and a second repair signal according to the second drive control signal and the comparison signal.

27. The semiconductor device of claim 26, wherein the drive control signal generator includes:
a first drive control signal generator configured to generate the first drive control signal according to whether the third fuse is cut or not in response to the fuse control signal and the pulse of the first control signal; and
a second drive control signal generator configured to generate the second drive control signal according to whether the fourth fuse is cut or not in response to the fuse control signal and the pulse of the second control signal.

28. The semiconductor device of claim 27, wherein the first drive control signal generator includes:
the third fuse having a first end electrically connected to a power voltage terminal and a second end electrically connected to a fourth node;
a first driver having a first end electrically connected to the fourth node and a second end electrically connected to a ground terminal; and
a first buffer electrically connected to a fifth node acting as an output terminal of the first driver,
wherein the first driver drives the fifth node in response to the fuse control signal and the pulse of the first control signal, and the first buffer buffers a signal of the fifth node to generate the first drive control signal.

29. The semiconductor device of claim 28, wherein the first driver pulls down a voltage level of the fifth node while the fuse control signal is enabled and pulls up a voltage level of the fifth node while the pulse of the first control signal are inputted.

30. The semiconductor device of claim 28, wherein the third fuse comprises an anti-fuse.

31. The semiconductor device of claim 27, wherein the second drive control signal generator includes:
the fourth fuse having a first end electrically connected to a power voltage terminal and a second end electrically connected to a sixth node;
a second driver having a first end electrically connected to the sixth node and a second end electrically connected to a ground terminal; and
a second buffer electrically connected to a seventh node acting as an output terminal of the second driver,
wherein the second driver drives the seventh node in response to the fuse control signal and the pulse of the second control signal, and the second buffer buffers a signal of the seventh node to generate the second drive control signal.

32. The semiconductor device of claim 31, wherein the second driver pulls down a voltage level of the seventh node while the fuse control signal is enabled and pulls up the voltage level of the seventh node while the pulse of the second control signal is inputted.

33. The semiconductor device of claim 31, wherein the fourth fuse comprises an anti-fuse.

34. The semiconductor device of claim 26, wherein the repair signal generator includes:
a first repair signal generator configured to generate the first repair signal according to the first drive control signal and the comparison signal in response to a first comparison control signal including a pulse generated after a first delay time from a point of time that the row address enable signal is enabled; and
a second repair signal generator configured to generate the second repair signal according to the second drive control signal and the comparison signal in response to a second comparison control signal including a pulse generated after a second delay time from a point of time that the pulse of the first comparison control signal occurs.

35. The semiconductor device of claim 34, wherein the first repair signal generator pulls down a voltage level of a eighth node while the pulse of the first comparison control signal does not occur and pulls up a voltage level of the eighth node according to the first drive control signal and the comparison signal while the pulse of the first comparison control signal occurs.

36. The semiconductor device of claim 34, wherein the second repair signal generator pulls down a voltage level of a ninth node while the pulse of the second comparison control signal does not occur and pulls up a voltage level of the ninth node according to the second drive control signal and the comparison signal while the pulse of the second comparison control signal occurs.
